(19) United States
(12) Patent Application Publication
(10) Pub. No.: US 2014/0226267 A1
(43) Pub. Date: Aug. 14, 2014

(54) DISPLAY DEVICE

(71) Applicant: Panasonic Corporation, Osaka (JP)

(72) Inventors: Shuji YAMASHITA, Nara (JP); Suguru NAKAO, Hyogo (JP); Hiromi KANZAWA, Osaka (JP); Naoto TADA, Osaka (JP); Kazuya HONDA, Osaka (JP)

(73) Assignee: Panasonic Corporation, Osaka (JP)

(21) Appl. No.: 14/135,535

(22) Filed: Dec. 19, 2013

Related U.S. Application Data
(63) Continuation of application No. PCT/JP2013/003167, filed on May 17, 2013.

(30) Foreign Application Priority Data
Feb. 12, 2013 (JP) 2013-023988

(51) Int. Cl. G02B 5/08; H05K 5/00

(52) U.S. Cl. CPC G02B 5/08; H05K 5/0017
USPC 361/679.01

(57) ABSTRACT

A display device of the present disclosure includes: a display portion including a display face; a frame-shaped casing disposed so as to surround the display portion; and a decorative member disposed in contact with the casing. The decorative member is a light-transmissive member, and includes: a decorative portion forming a front face; and an attachment portion fixed to the casing and forming a back face opposite to the front face. The decorative member has formed therein a reflecting face configured to reflect light that is incident through the front face and travels in an inside of the decorative member along an optical axis direction perpendicular to the display face, and thereby to produce reflected light that travels in a direction different from the optical axis direction.

This is a continuation of International Application No. PCT/JP2013/003167, with an international filing date of May 17, 2013, which claims the foreign priority of Japanese Patent Application No. 2013-023988, filed on Feb. 12, 2013, the entire contents of both of which are hereby incorporated by reference.

### BACKGROUND OF THE INVENTION

1. Field of the Invention

The present disclosure relates to a display device including: a display portion including a front face having a function of displaying information; and a casing disposed around the display portion. Specifically, the present disclosure relates to a display device that is a stationary display for flat-screen televisions etc. or that is a portable display for smartphones, tablet computers etc.

2. Description of Related Art

A display device that includes a tabular display module as a display portion, such as a liquid crystal display device and an organic EL (electroluminescence) display device, usually has a frame-shaped casing surrounding the display portion (e.g., JP 2006-53528 A). A decorative member is disposed on the periphery of the casing in some cases, in order to improve the commercial value of the display device.

### SUMMARY OF THE INVENTION

A light-transmissive decorative member is useful from the standpoint of improvement in decorativeness. However, a study by the present inventors has confirmed that, in the case of a display device having a light-transmissive decorative member attached to a casing, an image of a structure composed of, for example, members provided on the back face side of the decorative member may be reflected in the front face of the decorative member, leading to impairment of the commercial value of the design of the display device.

In view of the above, one non-limiting and exemplary embodiment provides a novel display device using a light-transmissive decorative member adapted to improve the commercial value of the design of the display device.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

In one general aspect, the techniques disclosed here feature a display device including: a display portion including a display face having a function of displaying information; a frame-shaped casing disposed so as to surround the display portion; and a decorative member disposed in contact with the casing. The decorative member is a light-transmissive member. Assuming that a direction perpendicular to the display face is an optical axis direction, then the decorative member includes: a decorative portion forming a front face visible from a position spaced from the display face in the optical axis direction; and an attachment portion fixed to the casing and forming a back face opposite to the front face. The decorative member has formed therein a first reflecting face configured to reflect light that is incident through the front face and travels in an inside of the decorative member along the optical axis direction, and thereby to produce reflected light that travels in a direction different from the optical axis direction.

These general and specific aspects may be implemented using a system, a method, a computer program, and any combination of systems, methods, and computer programs.

According to the present disclosure, a structure provided on the back face side of a light-transmissive decorative member is less visible from the front face side. According to the present disclosure, therefore, it becomes easy to improve the commercial value of the design of a display device by use of a light-transmissive decorative member.

### BRIEF DESCRIPTION OF THE DRAWINGS

FIG. 1 is a perspective view showing a display device according to an embodiment of the present disclosure.

FIG. 2 is a perspective view showing a part of a display device according to an embodiment of the present disclosure.

FIG. 3 is an exploded perspective view showing the structure of the part shown in FIG. 2.

FIG. 4 is a partial cross-sectional view showing the structure of a key part of a display device according to an embodiment of the present disclosure.

FIG. 5 is a partial cross-sectional view showing the structure of a key part of a display device according to another embodiment of the present disclosure.

FIG. 6 is a partial cross-sectional view showing the structure of a key part of a display device according to still another embodiment of the present disclosure.

FIG. 7 is a partial cross-sectional view showing the structure of a key part of a display device according to still another embodiment of the present disclosure.

FIG. 8 is a partial cross-sectional view showing the structure of a key part of a display device according to still another embodiment of the present disclosure.

FIG. 9 is a diagram for illustrating the angle of a reflecting face R with respect to light L traveling in an optical axis direction D.

FIG. 10A is a partial cross-sectional view showing the structure of a key part of a display device using a light-transmissive decorative member that does not have a first reflecting face.

FIG. 10B is a perspective view for illustrating a situation where, in a display device using the light-transmissive decorative member shown in FIG. 10A, an image of a structure provided on the back face side is reflected in the front face.

### DETAILED DESCRIPTION

Hereinafter, embodiments of the present disclosure will be described with reference to the drawings. However, the following description is not intended to limit the present disclosure to the embodiments.

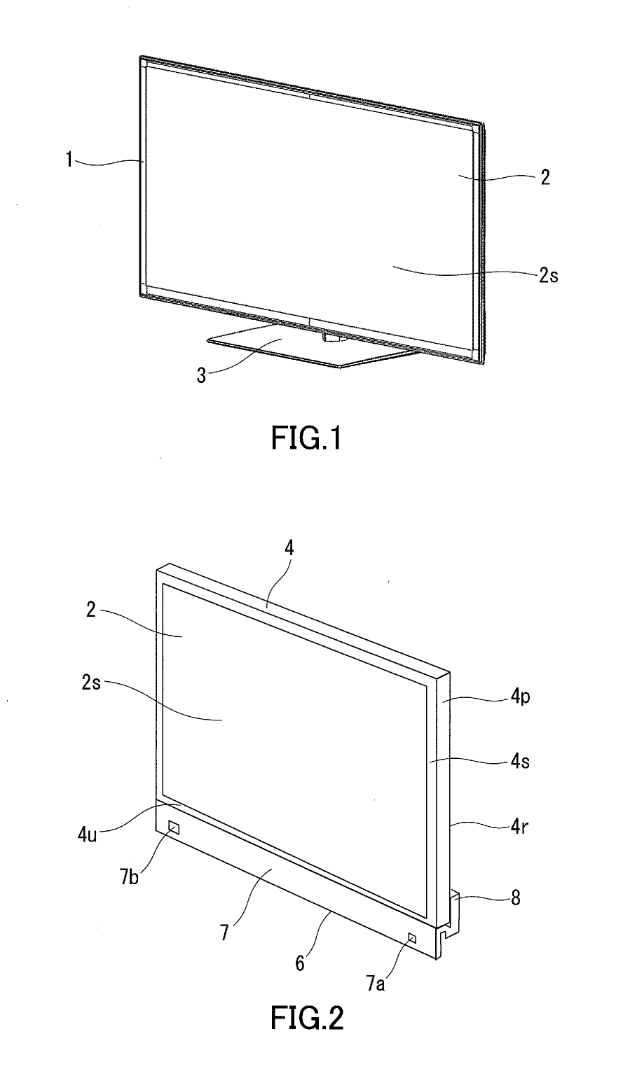

The display device shown in FIG. 1 includes: a display portion 2 composed of a tabular display module; and a housing 1 enclosing the display portion 2 in such a manner that a display face 2s of the display portion 2 is exposed. The display module is specifically a liquid crystal display device, an organic EL display device, or the like. The display face (front face) 2s of the display portion 2 is a flat, rectangular face having an information display function of displaying images etc. The display device shown in FIG. 1 is a stationary display, and further includes a stand 3 for stationarily supporting the display portion 2 in such a manner that the display face 2s is held substantially vertically. The display device may include another member such as a protection glass covering the display face 2s.

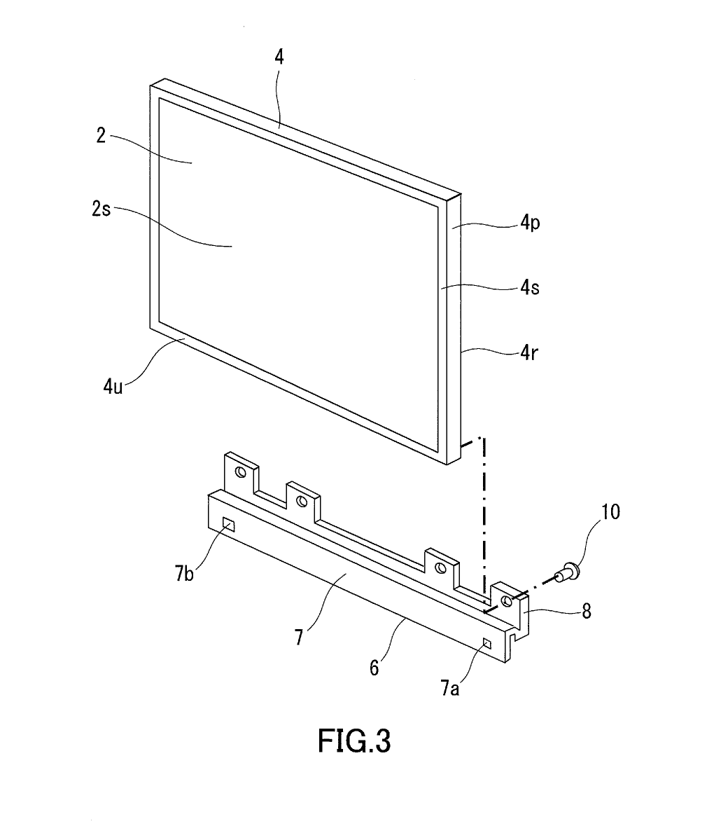

As shown in FIG. 2 to FIG. 4, the housing 1 includes a frame-shaped casing 4 disposed so as to surround the display portion 2, and a back cover 5 (omitted from FIG. 2 and FIG. 3) covering the back face (the face opposite to the display face) of the display portion 2. The casing 4 is a frame-shaped member covering the side faces of the display portion 2, and is constituted by four rod-shaped bodies joined together. The casing 4 has a front face 4s exposed on the same side as the display face 2s, a back face 4r exposed on the opposite side to the front face 4s, and outer peripheral faces 4p connecting the front face 4s to the back face 4r. The casing 4 and the back cover 5 are each an opaque member formed of metal, resin, or the like. Since the tabular display portion 2 is covered by the casing 4 and the back cover 5, the faces of the display portion 2 other than the display face 2s, i.e., the side and back faces, are not visible from the outside.

The display device further includes a decorative member 6, and the decorative member 6 is disposed in contact with the casing 4. The decorative member 6 is disposed in contact with the outer peripheral face 4p and a back face 4r of a lower member 4u which is one of the four rod-shaped bodies constituting the casing 4. The decorative member 6 is fixed to the back face 4r by use of a fastener 10. The fastener 10 is not particularly limited. For example, a screw is used as the fastener 10.

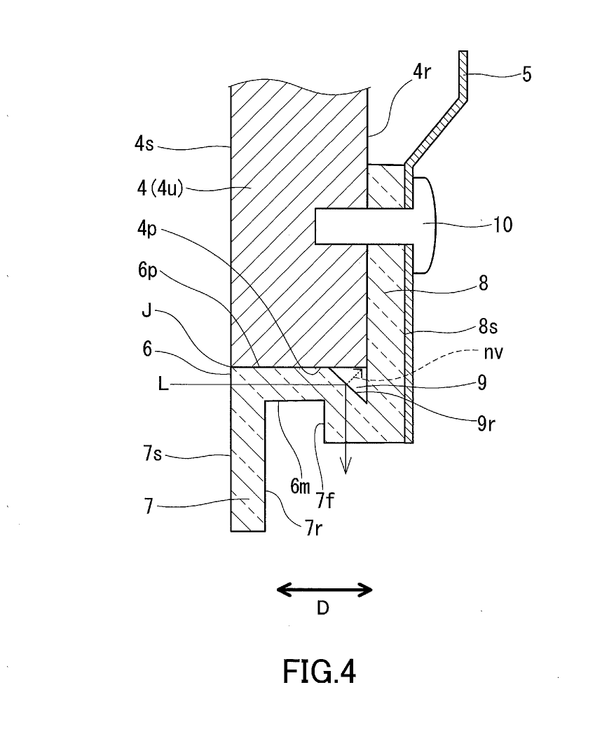

As shown in FIG. 4, the decorative member 6 includes a decorative portion 7 forming a front face 7s, and an attachment portion 8 fixed in contact with the back face 4r of the casing 4 and forming a back face 8s opposite to the front face 7s. Assuming that a direction perpendicular to the display face 2s is an optical axis direction D, then the front face 7s of the decorative member 6 is a face that is visible from a position spaced from the display face 2s in the optical axis direction D. Similarly to the front face 4s of the casing 4, the front face 7s is exposed on the same side as the display face 2s (on the front face side of the display device). The back face 8s of the decorative member 6 is located on the right of the back face 4r of the casing 4 in the figure. In other words, the back face 8s is located at a position rearward (on the right in the figure) of the back face 4r in the optical axis direction D. In the present specification, the term “back face of the decorative member” means the back face 8s of the attachment portion 8, and is not intended to include, for example, a rear face 7r that is opposite to the front face 7s in the decorative portion 7. The rear face 7r is formed as a face parallel to the front face 7s.

As shown in FIG. 2 and FIG. 3, an indicator 7a for displaying power-on/power-off, a light receiving portion 7b for a remote controller, and the like, are exposed on the front face 7s of the decorative member 6. The indicator 7a is composed of, for example, a light-emitting diode. Thus, the decorative member 6 not only exerts a decorative effect but also serves to provide a face for disposing functional elements.

The fastener 10 is principally intended to fix the back cover 5 to the casing 4, and functions also as a member that fixes the decorative member 6 by fixing the attachment portion 8 of the decorative member 6 to the back face 4r of the casing 4 together with the back cover 5.

The decorative member 6 is a light-transmissive member, and is a transparent member formed of, for example, a transparent resin such as an acrylic resin. The light transmissivity of the decorative member 6 is a desirable property contributable to improvement of the commercial value of the design of the display device. However, if an image of the attachment structure provided on the back face 8s side, or, specifically, an image of the structure composed of the members such as the back cover 5 and the fastener 10, were reflected in the front face 7s of the decorative member 6 due to the light transmissivity possessed by the decorative member 6, the improvement of the commercial value provided by the light transmissivity would be hindered.

The positions and shapes of the members such as the back cover 5 and the fastener 10 are restricted for the sake of attachment structure. Therefore, it is not necessarily easy to prevent the image reflection by improving these members. In addition, since the decorative member 6 functions as a light guiding member, light incident through the front face 7s reaches the vicinity of the attachment members by a roundabout route in some cases. Furthermore, it is also conceivable that an image of an aesthetically undesirable structure, which may be located on the back face 8s side depending on the installation location of the display device, is reflected in the front face 4s when light incident through the front face 7s travels straight and passes through the back face 8s.

As shown in FIG. 4, a reflecting face (first reflecting face) 9r is formed in the decorative member 6. The reflecting face 9r reflects light L incident through the decorative portion 7 and traveling in the optical axis direction D toward the back face, and produces reflected light traveling in a direction different from the optical axis direction D, or, in other words, in a direction intersecting the optical axis direction D. Therefore, the light L cannot reach the back face 8s of the decorative member 6 to cause reflection of an image of the structure provided on the back face side.

In practice, light is incident on the decorative member 6 from various directions. However, checking for the image reflection with respect to the direction (optical axis direction) D perpendicular to the display face 2s, i.e., the usual direction in which a user watches the display device, is adequate as a way to evaluate the commercial value of the display device.

The reflecting face 9r is a surface of the decorative member 6, and reflects the light L in a direction away from the casing 4. A normal vector nv of the surface of the decorative member 6 that serves as the reflecting face 9r configured to reflect light in the above manner extends toward the casing 4 and the back face 8s.

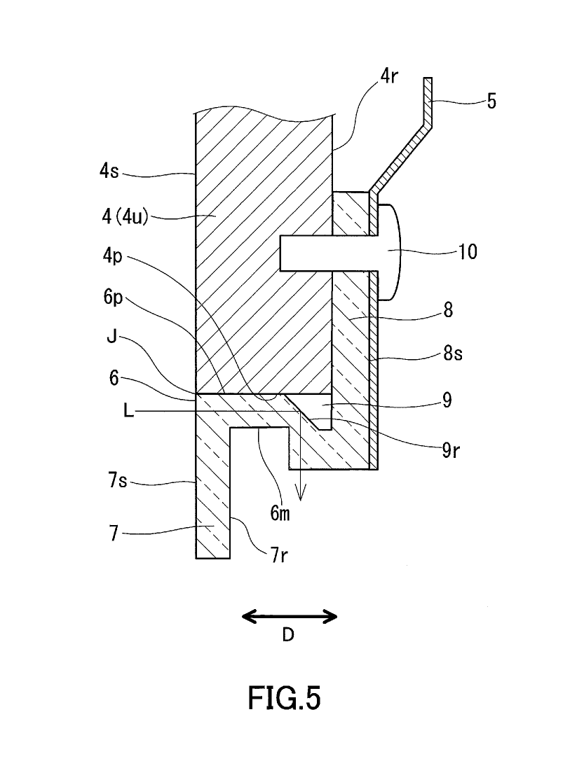

The reflecting face 9r is a surface of a groove portion 9 formed in the decorative member 6. A part of a surface 6p of the decorative member 6 that faces the casing 4 recedes away from the casing 4, and thus the groove portion 9 is formed. The casing 4 and the other members do not extend into the groove portion 9. That is, the groove portion 9 is present as an empty space. One desirable example of the cross-sectional shape of the groove portion 9 is a V shape shown in FIG. 4. However, the shape of the groove portion 9 is not limited to the V shape. An embodiment in which the groove portion 9 has a trapezoidal shape is shown in FIG. 5. The cross-sectional shape of the groove portion 9 is described for a cross-section (the cross-section shown in FIG. 4 and FIG. 5) orthogonal to the lengthwise direction of the casing's lower member 4u with which the decorative member 6 is in contact.

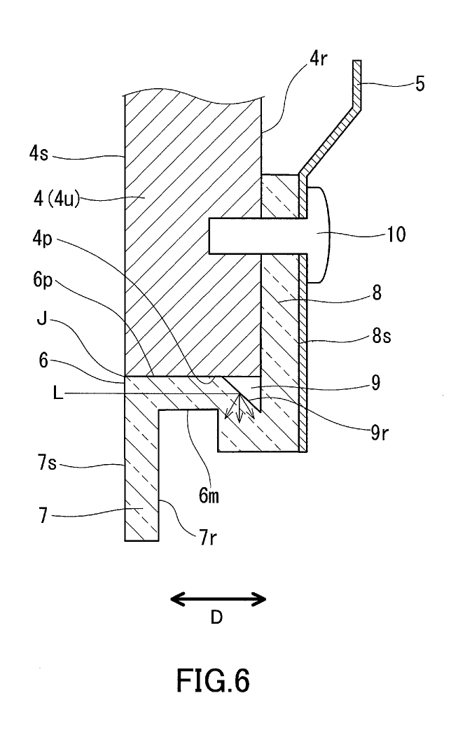

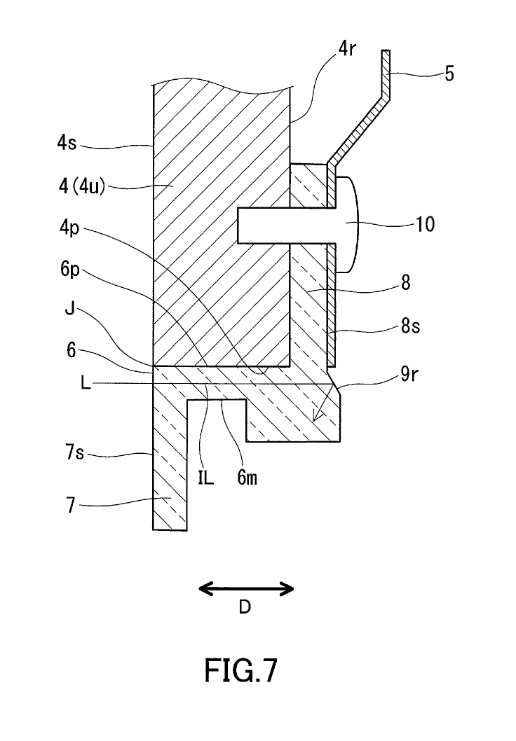

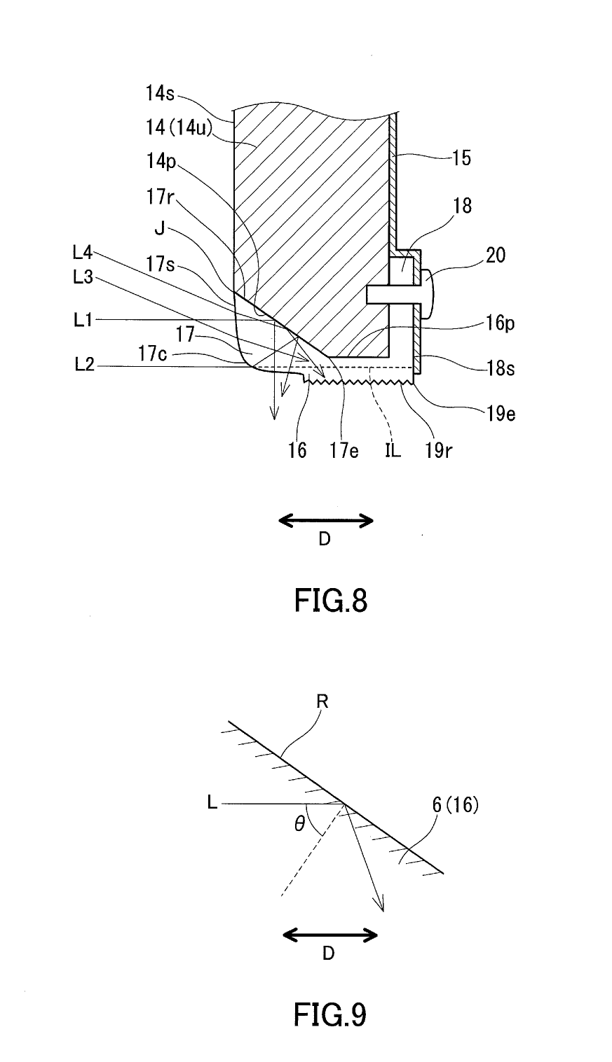

The reflecting face 9r need not be a flat face, but may be a curved face. In addition, the reflecting face 9r may be a smooth face (FIG. 4 to FIG. 5, and FIG. 7 to FIG. 8 described later), or may be a roughened surface of the decorative member 6. Even in the case where the reflecting face 9r is a roughened surface, it is possible to prevent the light L from causing an image of the structure provided on the back face 8s side to be reflected in the front face 7s. FIG. 6 shows reflected light produced in the case where the reflecting face 9r shown in FIG. 4 is a roughened surface. Since the reflected light from the roughened reflecting face 9r is scattering light, there is a possibility that reflected light that travels in a direction toward the casing 4, or reflected light that travels along the optical axis direction D, is produced by the reflecting face 9r. However, as in the case of FIG. 4, the reflecting face 9r shown in FIG. 6 also produces reflected light that travels in a direction away from the casing 4.

In the inside of the decorative member 6 shown in FIG. 4 to FIG. 6, there is no light path (internal light path) in which light travels straight along the optical axis direction D from the front face 7s to the back face 8s only through the inside of the decorative member 6. This reliably prevents images of the members disposed on the back face 8s from being reflected in the front face 7s. This desirable structure is achieved by the reflecting face 9r blocking the internal light path.

Some light traveling below the light L in FIG. 4 is incident on the decorative portion 7 through the front face 7s along the optical axis direction D. The light that travels straight through the rear face 7r and the opposing face 7f without being reflected by these faces 7r and 7f is incident on the back face 8s along the optical axis direction D. Although this light merely causes a limited reduction in design quality, the opposing face 7 (or the rear face 7r) may be roughened from the standpoint of further aesthetic improvement.

The reflecting face 9r shown in FIG. 4 to FIG. 6 is located between the decorative portion 7 and the attachment portion 8, or, to be more precise, between the front face 7s and the back face 8s of the decorative member 6. However, the reflecting face 9r may be a part of the back face 8s of the decorative member 6. In the decorative member 6 shown in FIG. 7, a part of the back face 8s functions as the reflecting face 9r. In FIG. 7, there is a light path IL in which light travels straight along the optical axis direction D from the front face 7s to the back face 8s only through the inside of the decorative member 6. However, the light L travelling in the light path IL is not perpendicularly incident on the back face 8s (reflecting face 9r). Therefore, the light L is reflected in a direction different from the optical axis direction D, and does not cause reflection of an image of the structure provided on the back face side. As shown in FIG. 4 to FIG. 7, the remaining part of the back face 8s that is not used as the reflecting face 9r is usually formed as a face perpendicular to the optical axis direction D, similarly to the front face 7s in these figures.

As shown in FIG. 4 to FIG. 7, in the inside of the decorative member 6, there is no internal light path IL in which light travels straight along the optical axis direction D from the front face 7s to the back face 8s only through the inside of the decorative member 6 and is perpendicularly incident on the back face 8s. Therefore, the decorative member 6 is adapted to reliably prevent reflection of an image of the structure provided on the back face side.

A surface of the decorative member that is in contact with the casing may be formed as a reflecting face. In a decorative member 16 shown in FIG. 8, light L1 incident through the decorative portion 17 and traveling along the optical axis direction D toward a back face 18s is reflected in a direction different from the optical axis direction D by a reflecting face 17r that is in contact with a casing 14 (specifically, a lower member 14u of the casing). Unlike in the case of the reflecting face 9r, the casing 14 extends into the receding portion of the decorative member 16 that is provided to form the reflecting face 17r. The surface of the decorative member 16 that is in contact with the casing 14 is suitable as the reflecting face 17r because such a surface is capable of reliably preventing transmission of light.

The reflecting face 17r and the reflecting face 9r (see FIG. 4 to FIG. 7) are similar in that each of the reflecting face 9r and the reflecting face 17r is a part of the surface 6p or 16p of the decorative member 6 or 16 that faces the casing 4 or 14, and is inclined with respect to the optical axis direction D or, more specifically, inclined in such a manner that light incident on the reflecting face along the optical axis direction D is reflected in a direction away from the casing 4 or 14. To be more exact, the surface 6p or 16p of the decorative member 6 or 16 that faces the casing 4 or 14 is a surface of the decorative member 6 or 16 that abuts on the outer peripheral face 4p or 14p of the casing, and the expression “inclined with respect to the optical axis direction D” means being inclined in a cross-section orthogonal to the lengthwise direction of the casing's lower member 4u or 14u with which the decorative member 6 or 16 is in contact. Not a part of the surface 6p or 16p but the entire surface 6p or 16p may be inclined. Namely, it is desirable that the reflecting face for preventing the image reflection be at least a part of the surface of the decorative member that faces the casing, and inclined with respect to the optical axis direction.

A curved face 17c is formed in the front face 17s of the decorative member 16, the curved face 17c receding away from the casing 14 toward the back face 18s. In other words, the curved face 17c is inclined with respect to the front face 14s of the casing 14 and the display face 2s of the display portion 2 in such a manner that the inclination increases with distance from the casing 14. If light L2 incident on the decorative member 16 along the optical axis direction D traveled straight without refraction, the light L2 would not be incident on the reflecting face 17r. However, in fact, the light L2 is refracted at the curved face 17c in a direction toward the casing 14, and is thus reflected at the reflecting face 17r. The refraction at the front face 17s prevents the light L2 from passing through the internal light path IL extending from the front face 17s to the back face 18s along the optical axis direction D, and thus prevents the light L2 from causing an image of the structure provided on the back face 18s side to be reflected in the front face 17s. Thus, the front face 17s of the decorative member 16 desirably has the inclined face 17c inclined with respect to the display face 2s in such a manner that light incident along the optical axis direction D is refracted in a direction different from the optical axis direction D, and is thus incident on the reflecting face 17r. The inclined face 17c may be a flat face. Also in the case where the inclined face 17c is a flat face, the refraction effect shown diagrammatically for the light L2 can be obtained similarly.

The curved face 17c shown in FIG. 8 is a convex face, and thus performs a function as a lens for reducing the size of an image of an object. By virtue of this function, an image of the structure provided on the back face side is made inconspicuous even when, for example, the image of the structure is slightly visible by watching the display device in a direction different from the optical axis direction D.

The light L2 is refracted at the inclined face 17c, incident on the reflecting face 17r, and reflected at the reflecting face 17r in a direction toward the front face 17s. Since at least a part of light refracted at the inclined face 17c is reflected at the reflecting face 17r in a direction toward the front face 17s as described above, the prevention of reflection of an image of the structure provided on the back face side is further ensured.

In the case of the decorative member 16, as shown in FIG. 8, there is the internal light path IL in which light coming from the front face 17s is perpendicularly incident on the back face 18s along the optical axis direction D. However, in the inside of the decorative member 16, there is no light path in which light incident on the decorative member 16 along the optical axis direction D travels straight only through the inside of the decorative member 16 and is perpendicularly incident on the back face 18s. This is because, as described above, the light L2 incident on the front end of the internal light path IL along the optical axis direction D is refracted at the inclined face 17c, and is directed toward the reflecting face 17r without traveling in the internal light path IL. Therefore, a user viewing the display device along the optical axis direction D cannot visually recognize reflection of an image of the structure provided on the back face side (see light L1 and L2).

Attention needs to be paid to the fact that the light-transmissive decorative member functions as a light guiding member. This is because such a function creates the possibility that there is not a light path in which light travels straight through the inside of the decorative member, but a light path in which light is reflected at the surfaces of the decorative member and finally reaches the back face. For example, there is a possibility that light L3 shown in FIG. 8 is repeatedly reflected at the surfaces of the decorative member 16, reaches the vicinity of a fastener 20 of an attachment portion 18 of the decorative member 16 by a roundabout route, and causes reflection of an image of the structure provided on the back face side. Particularly in the case where there is a concern about such a roundabout travel of light, a reflecting face (second reflecting face) 19r is desirably formed by roughening a part of a surface of the decorative member 16. It is advantageous that the reflecting face 19r be formed on a surface of the decorative member 16 other than the front face 17s and the back face 18s. In the decorative member 16, light scattering by the reflecting face 19r prevents an image of the structure provided on the back face side from being reflected in the front face 17s even when the display device is watched in a direction other than the optical axis direction D.

Light reflected at the reflecting face (first reflecting face) 17r, such as the light shown as light L4, also has the possibility of causing the image reflection similarly to the light L3. In particular, a reflecting face such as the reflecting face 17r, on which light passing through the front face 17s is incident often at a large angle, is likely to produce reflected light that travels toward the back face 18s by a roundabout route. Therefore, the reflecting face (second reflecting face) 19r is desirably formed in such a manner that an edge 19e on the back face 18s side of the reflecting face 19r is closer to the back face 18s than an edge 17e on the back face 18s side of the reflecting face (first reflecting face) 17r. Setting the edge 19e at a rearward position close to the back face 18s makes it more likely that at least a part of light incident on the front face 17s and reflected at the reflecting face 17r is scattered by the reflecting face 19r.

It is sufficient that the reflecting face (second reflecting face) 19r be a roughened face that scatters light. The reflecting face 19r can be formed by transferring the surface pattern processed on a mold used for resin molding. Examples of roughened faces that can be formed by this technique include a knurled face. The reflecting face 19r can be formed also by a post-molding process as typified by sandblasting. Also when the reflecting face (first reflecting face) 9r or 17r is formed as a roughened face, the roughened face can be formed by pattern transfer from a mold simultaneously with molding, or by a post-molding process, as in the case of the reflecting face 19r.

An appropriate angle between the reflecting face (first reflecting face) R of the decorative member 6 or 16 and the optical axis direction D will be described with reference to FIG. 9. The reflecting face R is desirably formed in such a manner that the incident angle θ of light incident on the reflecting face R along the optical axis direction D is 35° to 55°, particularly 40° to 50°, and more particularly 42° to 48°. When the incident angle θ is too large, there is a high possibility that reflected light from the reflecting face R reaches the back face of the decorative member by a roundabout route. When the incident angle θ is too small, the proportion of the light reflected at the reflecting face is low, with the result that the transmitted light may cause the image reflection depending on the structures of the decorative member 6 or 16 and the other members located around the decorative member.

It goes without saying that the above-described reflecting faces (the first reflecting faces 9r and 17r, and the second reflecting face 19r) need not be a face that reflects all of the incident light. In the present specification, as long as reflected light is produced from incident light by a face, the face which produces the reflected light is regarded as a reflecting face irrespective of whether or not transmitted light is produced.

The front face 7s or 17s of the decorative member 6 or 16 shown in FIG. 4 to FIG. 8 forms a continuous face with the front face 4s or 14s of the casing. In other words, no stepped portion is formed at a junction portion J between the front face 7s or 17s and the front face 4s or 14s. The front face 7s or 17s and the front face 4s or 14s are visible from a position spaced from the display face 2s, and enter the field of view of a user. Therefore, from the standpoint of the commercial value of the design of the display device, these faces 7s or 17s and 4s or 14s are desirably flush with each other.

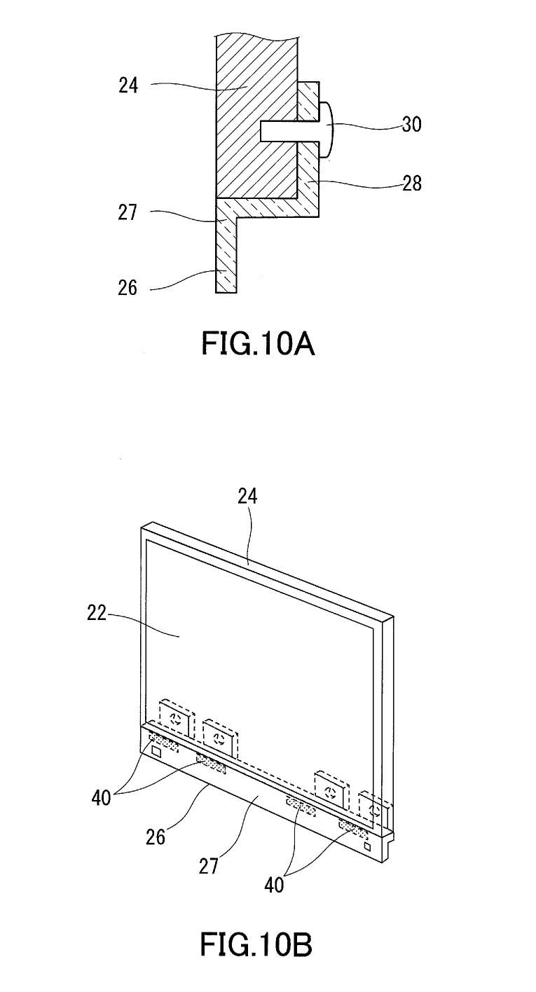

Last of all, image reflection observed in a light-transmissive decorative member that has no reflecting face will be described with reference to FIG. 10A and FIG. 10B. In the case of using a display device in which a light-transmissive decorative member 26 shown in FIG. 10A is fixed to the back face of a casing 24 by a fastener 30, an image of the structure provided on a back face 28 side is reflected in a decorative portion 27 of the decorative member 26 as shown in FIG. 10B. The reflected images 40 enter the field of view of a user viewing the display portion 22, and hinder the commercial value improvement provided by the light-transmissive decorative member 26.

The invention may be embodied in other forms without departing from the spirit or essential characteristics thereof. The embodiments disclosed in this specification are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A display device comprising: a display portion comprising a display face having a function of displaying information; a frame-shaped casing disposed so as to surround the display portion; and a decorative member disposed in contact with the casing, wherein
the decorative member is a light-transmissive member,
assuming that a direction perpendicular to the display face is an optical axis direction, then
the decorative member comprises:
a decorative portion forming a front face visible from a position spaced from the display face in the optical axis direction; and
an attachment portion fixed to the casing and forming a back face opposite to the front face, and
the decorative member has formed therein a first reflecting face configured to reflect light that is incident through the front face and travels in an inside of the decorative member along the optical axis direction, and thereby to produce reflected light that travels in a direction different from the optical axis direction.

2. The display device according to claim 1, wherein the first reflecting face is a surface of the decorative member, the surface being configured to cause the reflected light to travel in a direction away from the casing.

3. The display device according to claim 2, wherein the first reflecting face is inclined with respect to the optical axis direction, the face being at least a part of a surface of the decorative member, the surface facing the casing.

4. The display device according to claim 3, wherein
the decorative member comprises a groove portion formed by a part of the surface facing the casing, said part of the surface receding away from the casing, and
the first reflecting face is a part of a surface of the groove portion.

5. The display device according to claim 3, wherein the decorative member is in contact with the casing at the first reflecting face.

6. The display device according to claim 1, wherein the front face of the decorative portion has an inclined face inclined with respect to the display face in such a manner that light incident along the optical axis direction is refracted at the inclined face in a direction different from the optical axis direction, and is incident on the first reflecting face.

7. The display device according to claim 6, wherein at least a part of the light refracted at the inclined face and incident on the first reflecting face is reflected at the first reflecting face in a direction toward the front face.

8. The display device according to claim 1, wherein
the decorative member has formed therein a roughened second reflecting face for scattering light incident through the front face, and an edge on the back face side of the second reflecting face is closer to the back face than an edge on the back face side of the first reflecting face.

9. The display device according to claim 8, wherein the second reflecting face is formed at such a position as to scatter at least a part of light incident on the front face and reflected at the first reflecting face.

10. The display device according to claim 1, wherein, in the inside of the decorative member, there is no light path in which light incident on the decorative member along the optical axis direction travels straight only through the inside of the decorative member and is perpendicularly incident on the back face.
